(19) United States
(12) Patent Application Publication
(10) Pub. No.: US 2010/0084613 A1
(43) Pub. Date: Apr. 8, 2010

(54) SEMICONDUCTOR DOPING PROCESS

(75) Inventors: Ian Andrew Maxwell, New South Wales (AU); James Stanislaus Williams, Australian Capital Territory (AU); Jodie Elizabeth Bradby, Australian Capital Territory (AU); Simon Ruffell, Australian Capital Territory (AU); Naoki Fujisawa, Australian Capital Territory (AU)

Correspondence Address: KNOBBE MARTENS OLSON & BEAR LLP, 2040 MAIN STREET, FOURTEENTH FLOOR, IRVINE, CA, 92614, US

(73) Assignee: WRiota Pty Ltd., Sydney, New South Wales (AU)

(21) Appl. No.: 12/518,634

(22) PCT Filed: Dec. 13, 2007
(86) PCT No.: PCT/AU07/01931

§ 371 Date: Sep. 2, 2009

Related U.S. Application Data
(60) Provisional application No. 60/874,757, filed on Dec. 13, 2006.

(51) Int. Cl. H01B 1/04; H01L 21/263; H01L 21/66

(52) U.S. Cl. 252/500; 438/795; 438/5; 438/10; 257/E21.333; 257/E21.53; 257/E21.531

(57) ABSTRACT

A doping process, including applying pressure to at least one first phase of a semiconductor containing an electrically inactive dopant and removing the pressure to cause at least one phase transformation of the semiconductor to at least one second phase, wherein the at least one phase transformation activates the dopant so that the at least one second phase includes at least one doped phase of the semiconductor in which the dopant is electrically active.

### TECHNICAL FIELD

The present invention relates to a doping process, and in particular to a process for forming one or more regions of doped semiconductor.

### BACKGROUND

Semiconductors are particularly useful materials because their electrical conductivity can be changed by many orders of magnitude as a result of introducing small concentrations of certain atomic species, referred to generically as “dopants”. For example, in the case of the most ubiquitous semiconductor, silicon (Si), doped silicon is used to form electrically conductive paths or regions in integrated circuits, micro-electro-mechanical-systems (MEMS), flat panel displays, and other types of devices. In some applications, such as solar cells and the thin-film transistors (TFT) used for flat panel displays, a polycrystalline form of Si (referred to as “polysilicon”) is generally used. Typically, doped regions are formed from a surface layer formed on top of a substrate (which may itself be silicon and/or may already contain one or more other layers, structures, and/or devices), and the process of depositing and/or doping the surface layer involves heating the layer to temperatures in excess of about 600° C. during deposition and up to 900° C. to activate the dopants. However, the continual need to reduce the physical dimensions of features in integrated circuits and other types of devices has led to a consequent need to reduce the “thermal budget” (being a combination of one or more temperatures and the respective times spent at these temperatures) that the components of such devices are exposed to during manufacturing. Consequently, there has been an increasing demand to reduce the temperatures and/or the durations spent, particularly at the highest temperatures involved in such manufacturing.

Flat panel displays for devices such as televisions and computer displays are also manufactured by semiconductor processing based on silicon process technology. For example, TFT displays are manufactured by depositing a layer of amorphous silicon (referred to herein as “a-Si”) onto a planar glass substrate, and subsequently heating the a-Si to transform it to a polycrystalline phase of Si (poly-Si). To minimise the heating of the glass substrate, an excimer laser is used to generate a laser beam that is directed onto the a-Si layer in order to locally heat it to a temperature sufficient to crystallise the layer without melting the glass substrate. However, excimer lasers are unstable at the high powers required to rapidly achieve this phase transformation, and this greatly complicates the manufacturing process, making it less reliable and the resulting layers less uniform.

Consequently, alternative processes have been developed whereby poly-Si in nanocrystalline form is directly deposited at relatively low temperatures by, for example, chemical vapour deposition. However, the costs of such processes are substantially greater than those of amorphous Si deposition and moreover the quality and uniformity of TFTs made by these processes are questionable at this stage. Alternatively, various methods have been applied to crystallize amorphous Si at low temperatures but, again, all of these existing methods have limitations. The two basic approaches utilize either solid phase or melt-mediated crystallization. Solid phase methods normally involve the nucleation and growth of poly-Si at temperatures around 600° C. for some tens of hours (although the temperature can be reduced somewhat by adding metallic impurities to catalyse the process), or by using rapid thermal annealing at higher temperatures. However, crystallization temperatures in excess of about 350° C. are incompatible with the glass substrates on which TFTs are formed, and the resulting defect densities of the poly-Si films are too high for high performance TFTs.

In solar cell manufacturing, crystalline (i.e., single-crystal) and poly-crystalline solar cells are known to be more efficient than amorphous solar cells, and are thus preferred. However, today the only efficient means of making crystalline, poly-crystalline or multi-crystalline solar cells is in wafer form. For solar cell manufacturing, this is an undesirably expensive technology, and consequently there is a strong interest in depositing thin silicon layers directly on glass to make low cost solar cells. However, as described above, silicon deposited on glass is generally limited to amorphous silicon, and existing processes to convert the deposited amorphous silicon to doped poly-crystalline silicon require temperatures that are harmful to the glass substrate. Hence there is need for a process that converts amorphous silicon to doped poly-crystalline silicon at temperatures well below the glass transition temperature of the substrate glasses.

It is desired to provide a doping process that alleviates one or more of the above difficulties, or at least provides a useful alternative.

### SUMMARY

In accordance with the present invention, there is provided a doping process, including: applying pressure to at least one first phase of a semiconductor containing an electrically inactive dopant and removing said pressure to cause at least one phase transformation of said semiconductor to at least one second phase, wherein said at least one phase transformation activates said dopant so that said at least one second phase includes at least one doped phase of said semiconductor in which said dopant is electrically active.

Preferably, said applying and removal of pressure includes applying pressure to one or more localised regions of said semiconductor and removing said pressure to cause at least one phase transformation of said one or more localised regions of said semiconductor, wherein said at least one phase transformation activates said dopant to form one or more localised regions of a doped phase of said semiconductor.

Advantageously, the process may include heating said at least one second phase to transform said at least one second phase to at least one third phase, said at least one third phase including at least one doped phase of said semiconductor in which said dopant is electrically active; wherein said heating would be insufficient to thermally activate said dopant in said at least one first phase of said semiconductor in the absence of pressure-induced phase transformation.

Advantageously, the process may include heating said semiconductor during at least the removal of said pressure to cause the formation of said at least one doped phase; wherein said heating would be insufficient to thermally activate said dopant in said at least one first phase of said semiconductor in the absence of pressure-induced phase transformation.

Preferably, the process includes heating said semiconductor during the application of said pressure to facilitate a phase transformation of said semiconductor.

The present invention also provides a doping process, including:
applying pressure to at least one first phase of a semiconductor containing an electrically inactive dopant and removing said pressure to transform said semiconductor to at least one second phase; and
heating said at least one second phase to transform said at least one second phase to at least one third phase, said at least one third phase including at least one doped phase of said semiconductor in which said dopant is electrically active;
wherein said heating would be insufficient to thermally activate said dopant in said at least one first phase of said semiconductor in the absence of pressure-induced phase transformation.

Preferably, said semiconductor is silicon and said temperature is substantially below 600° C.

Preferably, said semiconductor is silicon and said temperature is at most about 450° C.

Preferably, said semiconductor is silicon and said temperature is at most about 175° C.

Preferably, said step of applying pressure to said semiconductor and removing said pressure to transform said semiconductor includes:
applying pressure to said semiconductor and removing said pressure;
determining whether said step (i) of applying and removing pressure has substantially transformed said semiconductor to said at least second phase; and
repeating steps (i) and (ii) until it is determined that said semiconductor has been substantially transformed to said at least one second phase.

Preferably, said step of determining whether said semiconductor has been substantially transformed includes determining a final surface displacement, the determination of whether said semiconductor has been substantially transformed to said at least second phase being made on the basis of said final surface displacement.

Preferably, said step of determining whether said semiconductor has been substantially transformed includes determining at least one electrical conductivity of said semiconductor, the determination of whether said semiconductor has been substantially transformed to said at least one second phase being made on the basis of said at least one electrical conductivity.

Preferably, said step of determining whether said semiconductor has been substantially transformed includes determining an I-V curve of said semiconductor, the determination of whether said semiconductor has been substantially transformed to said at least one second phase being made on the basis of said I-V curve.

Preferably, said at least one first phase of said semiconductor includes said at least one second phase of said semiconductor.

Preferably, said at least one first phase of said semiconductor does not include said at least one second phase of said semiconductor.

Preferably, said at least one doped phase includes at least one crystalline phase.

Preferably, said at least one first phase of said semiconductor includes an amorphous phase of said semiconductor.

Preferably, said amorphous phase is a relaxed amorphous phase.

Preferably, the process includes forming said relaxed amorphous phase by relaxing an unrelaxed amorphous phase of said semiconductor.

Preferably, said semiconductor is silicon.

The present invention also provides a doped semiconductor formed by any one of the above processes.

### BRIEF DESCRIPTION OF THE DRAWINGS

Preferred embodiments of the present invention are hereinafter described, by way of example only, with reference to the accompanying drawings, wherein:

FIG. 1 is flow diagram of a preferred embodiment of a doping process;

FIG. 2 is a graph showing the depth profiles of boron implanted into a silicon sample at energies of 10 and 20 keV, as predicted by Monte-Carlo simulation;

FIG. 3 is a graph of the relationship between applied load and penetration depth (also referred to as a “load/unload curve”) during indentation of a relaxed amorphous silicon layer on a crystalline silicon substrate;

FIG. 4 is a schematic diagram illustrating an indenter tip approaching a relaxed amorphous silicon layer on a crystalline silicon substrate;

FIG. 5 is a schematic diagram illustrating the indenter tip being pressed into and indenting the relaxed amorphous silicon layer, and the electrical circuit arrangement for measuring electrical conduction through the indented sample;

FIG. 6 is a graph of the I-V characteristics (current as a function of applied voltage) of two samples before and after indentation, the samples having been implanted with 10 keV, 10¹⁴ B cm⁻², illustrating the variations observed between different samples indented under nominally identical conditions;

FIGS. 7 to 9 are the same as FIG. 6, but for samples respectively implanted with boron at (i) 10 keV, to a fluence of 10¹⁵ B cm⁻², (ii) 20 keV, to a fluence of 10¹⁴ B cm⁻², and (iii) 20 keV, to a fluence of 10¹⁵ B cm⁻²;

FIG. 10 is a schematic illustration of an arrangement for measuring the electrical resistance of a strip of phase transformed material formed by the doping process;

FIG. 11 is a graph showing the current-voltage (I-V) characteristics of phase transformed silicon with and without implanted boron;

FIG. 12 is a schematic diagram illustrating an indented sample where the applied pressure was released relatively slowly from the indented region;

FIG. 13 is a schematic diagram illustrating the indented sample of FIG. 10 following low temperature annealing;

FIG. 14 is a graph showing the I-V characteristics of three indented samples following low temperature annealing;

FIG. 15 is a graph showing a set of I-V characteristics for phase transformed silicon for different subsequent low temperature annealing conditions;

FIG. 16 is a graph showing the load/unload curves for indentation of three samples that were not implanted with boron;

FIG. 17 is a graph showing the I-V characteristics of five samples that were not implanted with boron, after indentation and annealing at 450° C. for 30 mills;

FIG. 18 is a graph showing the Raman spectra from indented regions in a crystalline Si-I sample before and after annealing at 175° C., and from a Si-I sample;

FIG. 19 is a graph of the ‘crystallisation time’ (minimum annealing time to remove the peaks associated with high pressure phases in spectra such as those shown in FIG. 18) as a function of annealing temperature;

FIG. 20 is a schematic diagram illustrating the different phases in the indented regions before and after annealing, and their dependence on the rate of pressure release (the unloading rate);

FIG. 21 is a graph showing the load/unload curves for three samples processed under nominally identical conditions, illustrating the variations in final displacement that are observed in practice;

FIG. 22 is the same graph as FIG. 21, but with the load scaled to the two thirds power to facilitate the accurate determination of final indentation depth by extrapolation;

FIG. 23 is a graph of the cyclic load applied to the indenter tip as a function of time during cyclic indentation;

FIG. 24 is a graph of the corresponding current as a function of time for conduction through an indented region subjected to the cyclic load shown in FIG. 23; and

FIG. 25 is a schematic diagram illustrating the different phases of silicon formed by loading, unloading, reloading, and thermal annealing.

### DETAILED DESCRIPTION OF THE PREFERRED EMBODIMENTS

Crystalline diamond-cubic silicon (also referred to as Si-I, the ‘common’ silicon phase produced in wafer form for the manufacture of microelectronic devices) undergoes a series of phase transformations during mechanical deformation. High-pressure diamond anvil experiments have shown that crystalline diamond-cubic Si-I undergoes a phase transformation to a metallic β-Sn phase (also referred to as Si-II) at a pressure of ˜11 GPa, as described in J. Z. Hu, L. D. Merkle, C. S. Menoni, and I. L. Spain, Phys. Rev. B 34, 4679 (1986), and because Si-II is unstable at pressures below ˜10 GPa, the Si-II undergoes further transformation during pressure release. Such diamond-anvil studies have shown that the Si-II phase forms a mixture of the high-pressure phases Si-III and Si-XII (referred to hereinafter as “HPP”) on pressure release.

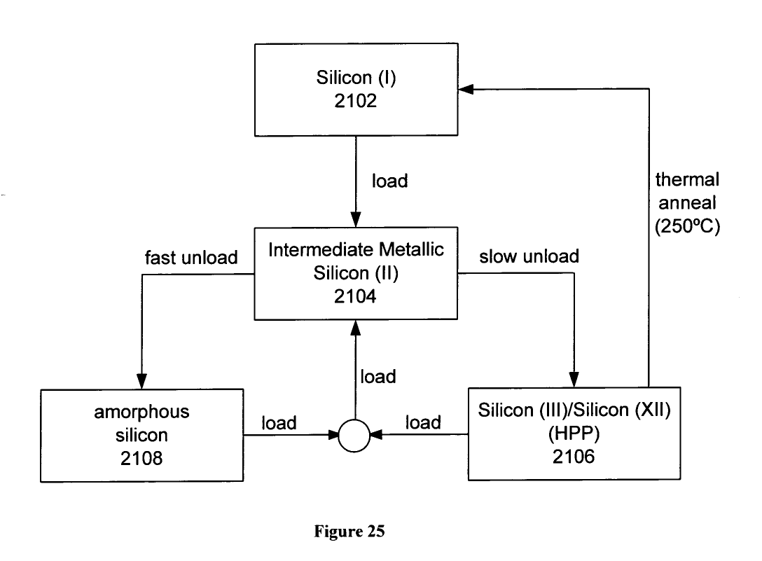

These phase transformations have also been observed to occur during a process referred to as indentation, wherein an extremely hard indenter tip is pressed into the surface of a material with the force applied to the indenter tip increasing to a maximum value over a period of time (referred to as the loading or applying phase or step of the indentation process), and this force is subsequently decreased over a period of time (referred to as the unloading or releasing phase or step of the indentation process) and the indenter tip removed from the deformed or indented surface. Indentation as described above is a well-established technique for evaluating material properties of substances, hardness in particular. FIG. 25 summarises the phase transformations that occur during indentation loading and unloading of Si-I 2102. As in diamond-anvil experiments, the initial Si-I phase 2102 transforms to the Si-II phase 2104 under pressure; i.e., during loading. On unloading, the Si-II phase 2104 undergoes additional transformations to form either the crystalline HPP phases 2106 or an amorphous phase (a-Si) 2108, depending on the rate of pressure removal. Fast unloading (e.g., corresponding to a rate of force release greater than about 3 mN s⁻¹ in the case of a 4.2 μm radius spherical indenter tip) leads to the formation of a-Si 2108, whereas slow unloading results in the formation of HPP 2106.

a-Si is an unusual phase in that it exhibits markedly different properties, depending on how it has been formed. Specifically, a-Si can exist in one of two states: an ‘unrelaxed’ state (e.g., as-deposited or directly after formation by ion-implantation at or below room temperature), and a ‘relaxed’ state (e.g., formed by annealing unrelaxed a-Si at 450° C.), and these two states have different properties. In particular, as-implanted (unrelaxed) a-Si has been found to be significantly softer than Si-I, whereas annealed (relaxed) a-Si has been found to have very similar mechanical properties to those of the crystalline state Si-I. The reason for these differences is not known.

For example, a continuous layer of unrelaxed a-Si can be prepared by ion-implantation of crystalline Si-I 102 with 600 keV Si ions to a fluence of at least about 3×10¹⁵ ions cm⁻² at liquid nitrogen temperature. After implantation, a sample produced in this manner can be annealed for 30 minutes at a temperature of 450° C. in an argon atmosphere to cause the unrelaxed a-Si to transform to ‘relaxed’ a-Si. The thicknesses of the relaxed and unrelaxed amorphous layers produced under these conditions have been measured to be ˜650 nm by Rutherford backscattering (RBS) with 2 MeV helium ions, demonstrating that the annealing process is not sufficient to recrystallize the a-Si layer, and the layer remains amorphous. Thus the relaxed and unrelaxed states are both amorphous states of silicon.

As described in International Patent Application No. PCT/AU2004/001735, indentation of a layer of unrelaxed a-Si does not generally transform the unrelaxed a-Si into any other phases, because the relatively soft unrelaxed a-Si flows out from under the indenter tip and consequently does not reach the pressure required to initiate phase transformation. However, if unrelaxed a-Si is constrained so that it can be subjected to the ˜11 GPa transformation pressure, then it also transforms to the metallic Si-II phase. This can be achieved by using indenter or other form of pressure applicator that applies pressure over a relatively large area, depending also on the thickness of unrelaxed a-Si, since, for example, relatively thin unrelaxed a-Si layers can result in the confinement of material under the pressure applicator. Consequently, the relaxing of a-Si is not required if the unrelaxed a-Si can be confined.

In contrast to unrelaxed a-Si, relaxed a-Si generally behaves like Si-I when indented. Thus on loading, relaxed a-Si transforms to the metallic Si-II phase 104. On unloading, the Si-II phase 104 undergoes further transformations, depending on the rate of pressure release. Slow unloading causes the Si-II to transform to a mixture of HPP 106 (and possibly a relatively small amount of a-Si within these phases), whereas fast unloading causes the Si-II to transform to a-Si. It is not clear whether the a-Si formed on unloading is in the relaxed or unrelaxed state, but this does not appear to influence its ability to transform to Si-II on subsequent re-indentation, presumably because the small indent-induced amorphous region is confined under the indenter and surrounded by material that does not flow on the application of pressure. Consequently, even if this amorphous material was in the unrelaxed state, it could not flow out from under the indenter, and would therefore be subjected to the high pressures required to transform it to the Si-II phase 104.

Moreover, heating the region of HPP in the relaxed amorphous Si layer to temperatures above about 175° C. causes the HPPs to undergo a further transformation to the Si-I phase (in polycrystalline form). Significantly, any amorphous Si within the transformed region containing HPPs is also transformed to Si-I. However, the relaxed a-Si that surrounds the indented region (i.e., relaxed a-Si that has not undergone any phase transformation) does not undergo the thermally-induced phase transformation to Si-I, even when heated to temperatures up to 450° C. for 30 minutes.

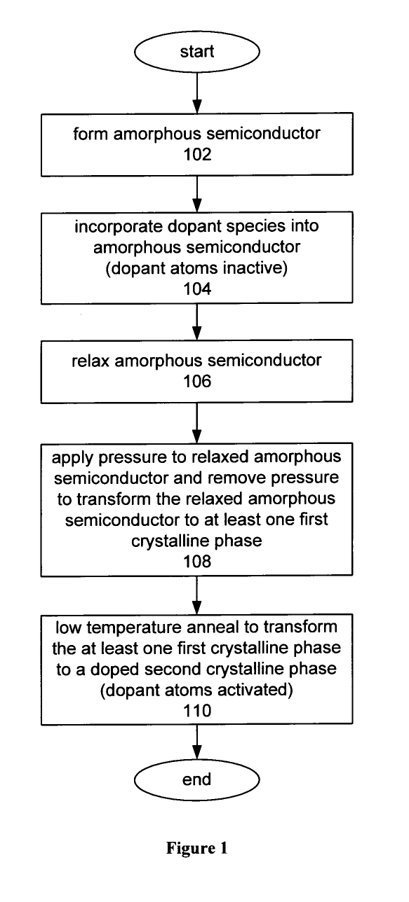

As shown in FIG. 1, a doping process begins by forming an amorphous semiconductor at step 102. In the described embodiment, the semiconductor is silicon, and a standard, commercially available wafer of (100) orientation grown by the Czochralski method (p-type, doped with boron to a resistivity of 8-12 Ω cm) is implanted with 50 keV silicon (Si) ions to a fluence of 1×10¹⁵ cm⁻² at liquid nitrogen temperature to form a surface amorphous layer having a thickness of about 100 nm. However, the amorphous surface layer could be formed by any one of a variety of alternative methods, including deposition by chemical vapour deposition (CVD), plasma-enhanced CVD (PECVD), sputtering, or attachment of a pre-existing amorphous layer using a bonding process, for example.

At step 104, a dopant species is introduced into the amorphous layer. In the described embodiment, the dopant species is boron, and boron atoms are introduced into the amorphous layer by ion implantation. The boron in the a-Si is not electrically active at this stage. However, it will be apparent to those skilled in the art that other dopant species could alternatively be incorporated into the amorphous silicon, and that the incorporation could be achieved by other means. For example, it could even be introduced at the same time as the amorphous layer is formed at step 102, or could already be incorporated into a pre-existing amorphous silicon layer or sample.

To demonstrate the doping process, four types of implanted samples were produced, implanted with boron at energies of either 10 keV or 20 keV, and to boron fluences of either 1×10¹⁴ cm⁻² or 1×10¹⁵ cm⁻². At step 106, each sample type was then heated to a temperature of 450° for 30 minutes to sharpen the interface between the amorphous layer and the underlying crystalline substrate, and in particular to relax the amorphous layer. No significant diffusion of boron occurs during this heating step.

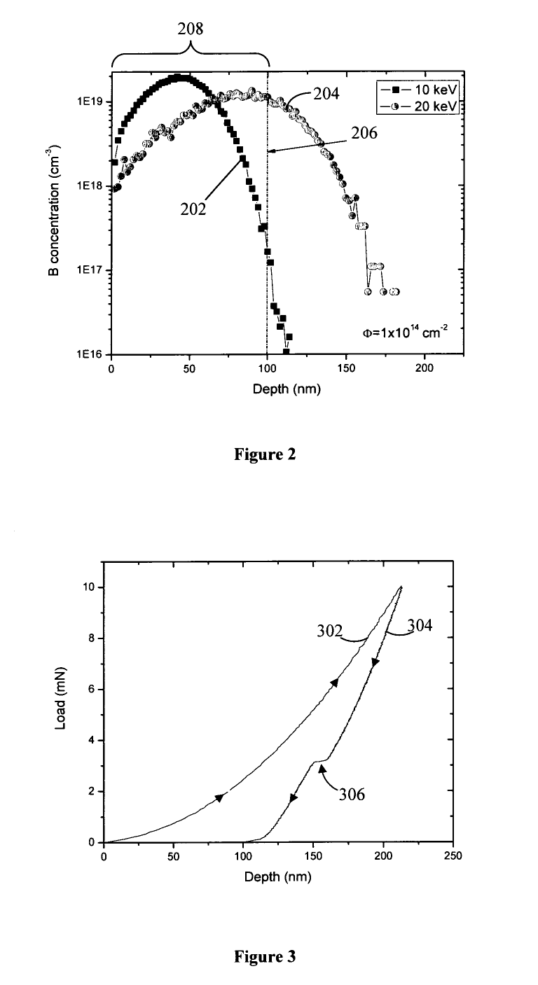

FIG. 2 is a graph of boron concentration as a function of depth in the samples implanted with 10 keV or 20 keV boron to the lower fluence of 1×10¹⁴ cm⁻², as predicted by the Monte-Carlo simulation software application SRIM (available from http://www.srim.org). The approximate 100 nm thickness of the surface amorphous layer is indicated by the vertical dashed line 206 and the bracketed region 208. It will be apparent that the lower energy 10 keV implant (represented by the shallow depth profile 202) places nearly all of the implanted boron within the surface amorphous layer, as evidenced by the observation that the concentration of boron at the amorphous-crystalline interface 206 is more than two orders of magnitude lower than the peak boron concentration, which is located at a depth of approximately 30 nm from the surface. In contrast, the depth profile 204 of boron implanted at the higher energy of 20 keV extends well beyond the amorphous-crystalline interface to a depth of approximately 150 nm or more, and the concentration of boron at the amorphous-crystalline interface is nearly equal to the peak boron concentration in these samples.

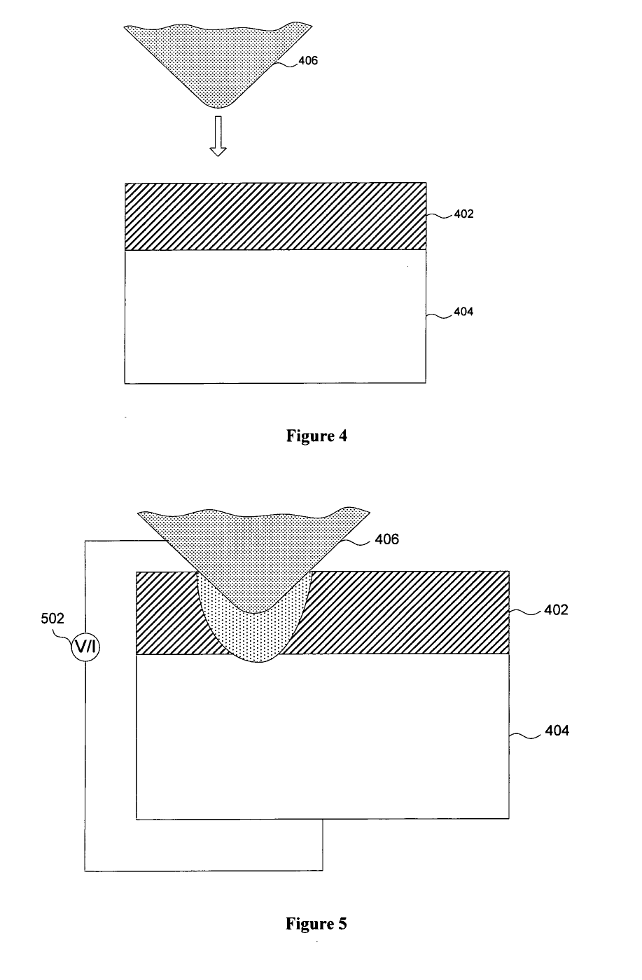

Returning to the flow diagram of FIG. 1, at step 108 pressure is applied to the relaxed amorphous layer and then removed to transform the relaxed amorphous layer to at least one first crystalline phase. To demonstrate the doping process, both Berkovich and spherical indenter tips were applied to different portions of each sample at pressures that lead to contact areas with dimensions ranging from less than 100 nm to more than 1 μm using a Hysitron Triboindenter, as shown schematically in FIGS. 4 and 5. As shown in FIG. 4, the indenter tip 406 is moved towards the relaxed amorphous layer 402 to contact the layer 402 and subsequently apply pressure to a portion of the layer 402 in order to transform it to other phases, as described above.

It is important to appreciate that different phase transformation outcomes can occur under different loading conditions. For example, given a particular semiconductor and a particular pressure applicator (which is described as being an indenter tip, but can of course take other forms, such as a planar punch, for example), the greater the maximum force applied to the pressure applicator, the larger the volume of material is subjected to pressures exceeding the phase transformation threshold and hence is transformed, in the case of silicon, to the intermediate metallic Si-II phase, leading to an increased probability of nucleating the HPP on unloading. Conversely, at lower maximum pressures, the volume of phase transformed material is smaller, and the probability of nucleating the HPP is thus lower.

FIG. 3 is a graph showing the relationship between the force or load applied to the indenter tip 406 and the resulting displacement of the sample surface below its initial location for indentation of Si-I with a spherical indenter tip with a 4.2 μm radius. The upper loading curve 302 of the resulting data shows the smooth and simple correlation between displacement and applied force or load, as the force is increased from 0 to approximately 10 mN (corresponding to an applied pressure that substantially exceeds the ˜11 GPa requires to form Si-II under the indenter) over a time period of 5 seconds, referred to as the “loading” phase of indentation. In the described embodiment where the relaxed amorphous semiconductor is silicon, the maximum load is selected such that, considering the geometry of the indenter tip, the resulting maximum pressure in the indented region surrounding the tip 406 substantially exceeds the pressure at which the relaxed amorphous silicon undergoes a phase transformation to a metallic β-Sn phase (also referred to as Si-II) as described above, which occurs at a pressure of about 11 GPa. Subsequently, that pressure is released completely, with the rate of pressure release of this “unloading phase” being selected or controlled to be sufficiently slow (less than about 3 mN s⁻¹ for the 4.2 μm radius spherical indenter tip) that the Si-II undergoes a further phase transformation to form a mixture of the Si-III/Si-XII phases, the occurrence of which is identified by the “pop-out” event 306 on the unloading curve 304 where the volume of transformed material increases with almost no change in the applied load (occurring in this instance at about 3 mN). The pop-out event 306 is caused by a sudden increase in the volume of material under the indenter tip resulting from the nucleation and rapid growth of a less dense phase (in this case, the transformation from the metallic Si-II phase to the mixed HPP). /

As shown in FIG. 5, the heavily doped diamond indenter tip 402 is connected to one output of a voltage/current supply 502, with the other output of the voltage/current supply 502 being connected to the conducting crystalline silicon (Si-I) substrate 404. This arrangement makes is possible to measure the electrical current that flows from the indenter tip 406 through to the substrate 404 as a function of applied voltage (i.e., I-V characteristics) before, during, and after indentation in order to gain information on the phases that form in the indented region. The I-V characteristics before and after indentation are measured by contacting the sample surface and applying a load of only 100 μN, which is well below that required to effect any phase transformation of silicon.

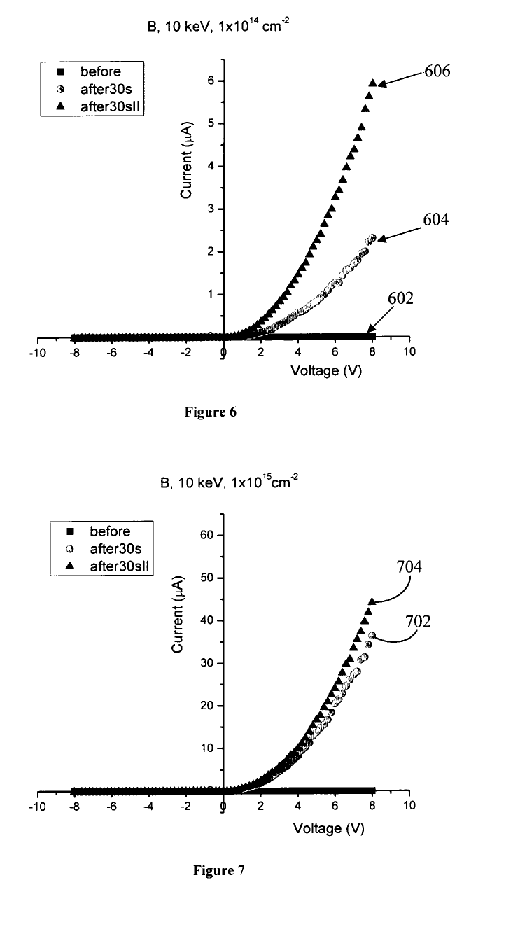

For example, FIG. 6 is a graph of the electrical current flowing through a sample as a function of applied voltage (i.e., the I-V characteristics) for two samples, each implanted with 10 keV boron ions to a fluence of 1×10¹⁴ cm⁻², both before and after indentation. Before indentation, essentially no current is conducted through the sample, as indicated by the square symbols 602 (which essentially lie on the x-axis). This is due to the presence of the relatively insulating amorphous layer 402 between the conductive indenter tip 406 and the conducting substrate 404. In contrast, after indentation the samples showed an electrically rectifying behaviour such that when the indenter tip 406 is biased positively with respect to the substrate 404, substantial electrical currents are conducted through the indented and transformed region, whereas essentially no current flows when the polarity is reversed, as indicated by the circular 604 and triangular 606 symbols for the two samples. This rectifying behaviour arises from a Schottky-like barrier between either the diamond tip 406 and the HPP, or the HPP and the underlying Si-I substrate 404. The variation in the electrical characteristics of different samples processed under nominally identical conditions (as evidenced by the substantial differences between the two sets of symbols 604, 606) is believed to be due to the statistical nature of the phase transformation processes, particularly for transformed regions less than a few hundred nanometres in diameter, as described further below.

FIG. 7 is similar to FIG. 6, showing the I-V characteristics of samples processed identically to those whose data is shown in FIG. 6, but for an order of magnitude higher boron fluence, namely 1×10¹⁵ cm⁻². As with the lower fluence samples, there is some variation in the magnitude of the forward bias currents, as shown by the two data sets respectively represented by circles 702 and triangles 704. Additionally, at this higher boron fluence, the forward currents are approximately an order of magnitude larger than the corresponding currents in the lower boron fluence samples for the same forward bias voltage. These data indicate that the boron is being electrically activated by the indentation process.

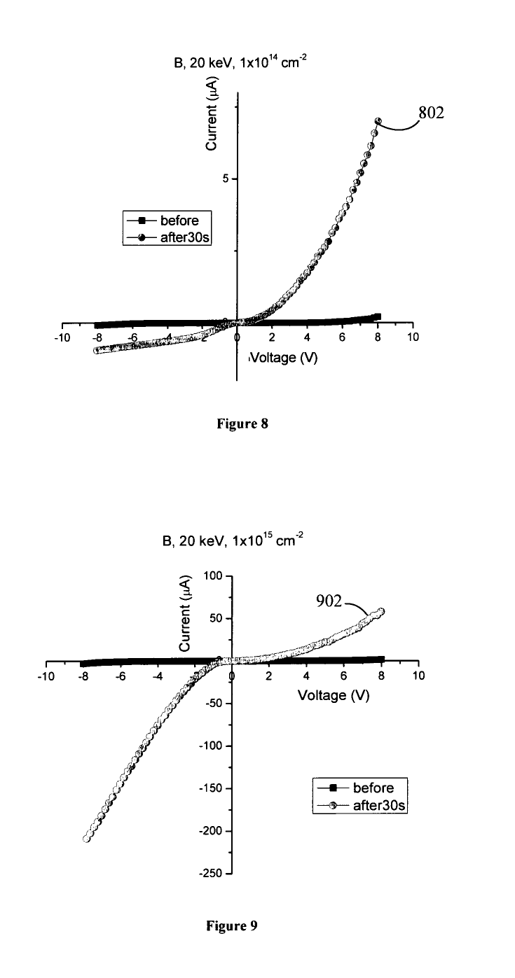

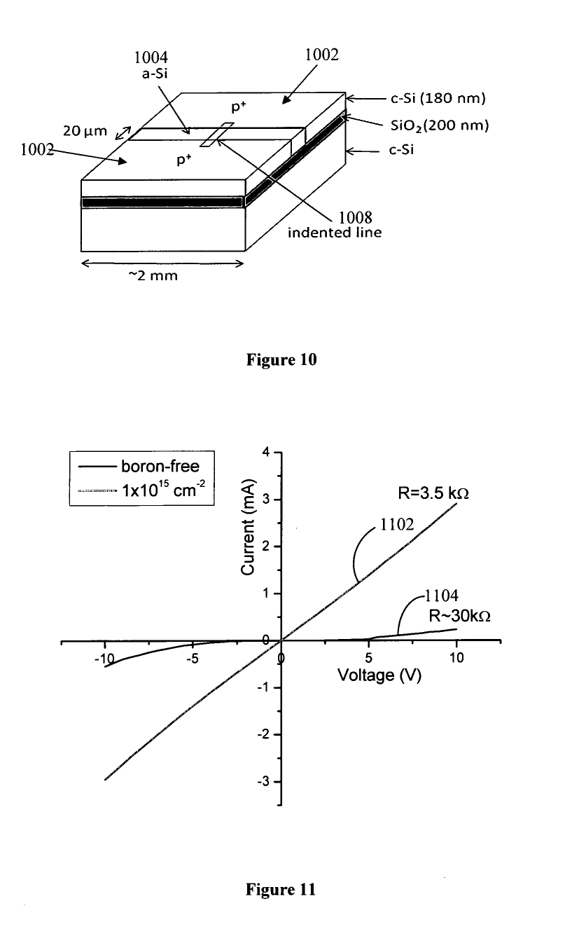

FIG. 8 is a graph showing the I-V characteristics 802 of a sample implanted with the lower boron fluence of 1×10¹⁴ cm⁻² but at the higher implantation energy of 20 keV. In comparison with the data of FIG. 6, it will be apparent that the same general rectifying characteristic is displayed, and in particular the forward bias characteristics are very similar. However, the indented region appears to be less rectifying than in the sample implanted at the lower boron energy, suggesting an Ohmic component in the current path through the indented region. This is even more apparent in FIG. 9 which shows the same data for a sample implanted at the higher fluence of 1×10¹⁵ cm⁻², where the reverse bias current is more Ohmic than rectifying. Regardless of these variations in behaviour between samples with different boron content and distribution, it is nevertheless clear from the marked differences in the I-V curves that the indentation has electrically activated the boron to produce doped silicon. Therefore, the I-V measurement is a useful indicator of phase transformation-induced dopant activation. FIG. 10 is a schematic illustration of a test structure in which two regions 1002 of highly doped (and therefore electrically conductive) crystalline silicon (Si-I) are separated (electrically isolated) by a 20 μm thick strip 1004 of electrically insulating amorphous silicon. The two conducting silicon regions 1002 and the insulating amorphous silicon strip form a 180 nm layer that is also electrically isolated from the substrate by a 200 nm thick silicon-dioxide layer 1006. By overlapping indentations, a continuous strip or line 1006 of high pressure phases (Si-III and Si-XII) can be created which extends from the surface down to the underlying silicon-dioxide layer 1006 and spans the amorphous silicon strip 1004, thus electrically connecting the two crystalline silicon regions 1002. By measuring the resistance between the two crystalline silicon regions 1002, the resistance of the continuous line or strip 1008 of high pressure phases (Si-III and Si-XII) is effectively measured.

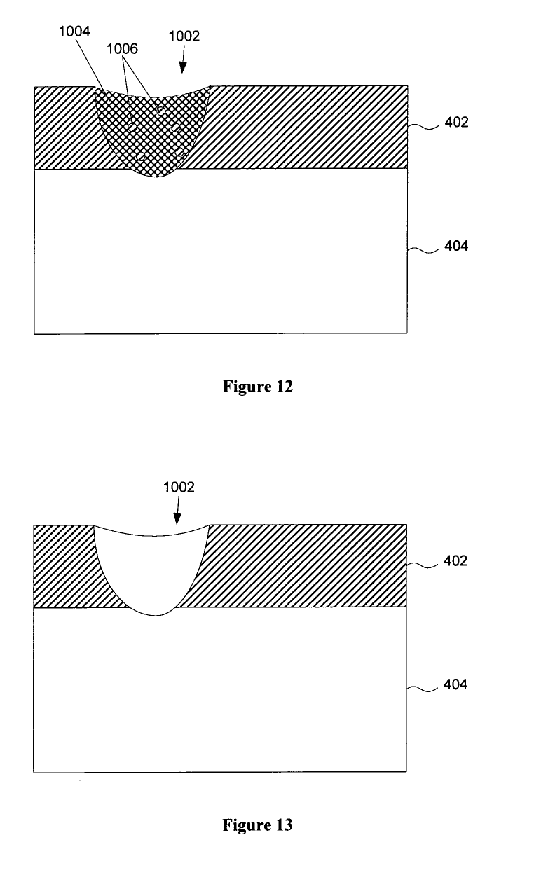

FIG. 11 is a graph showing I-V measurements of two such indented lines (the slope of the I-V curve provides the resistance). The upper curve 1102 is for an amorphous silicon strip containing implanted boron to a fluence of 1×10¹⁵ cm⁻². The lower curve 1104 is for an amorphous silicon strip that was not implanted with boron. The line of indented silicon (high pressure phases) in the boron-implanted silicon is an order of magnitude less resistive than the indented line in the boron-free sample, again indicating that the implanted boron is being electrically activated during the indentation process.

As shown schematically in FIG. 12, transmission electron microscopy analysis (not shown) of indented regions confirms that the physical structure of the indented region primarily consists of a mixture 1004 of the ‘high-pressure’ phases Si-III and Si-XII. However, depending on the rate of pressure release and the size of the transformed region, inclusions 1006 of amorphous silicon may be incorporated within the mixed phase region 1004, as described below.

The electrical measurements described above indicate that the boron dopant atoms are electrically active in the HPP, with the conductivity increasing with boron fluence. This indicates that the pressure-induced phase transformations activate the dopant atoms in an essentially a thermal manner. Standard doping processes are thermally activated, whereby a semiconductor containing electrically inactive dopant atoms is heated to a high temperature (e.g., around 900° C. in the case of silicon) in order to mobilise both the dopant atoms and the atoms of the host semiconductor so that the dopant atoms can replace atoms of the host semiconductor to become electrically active. In contrast, the pressure-induced phase transformation caused by the doping process described herein allows the dopant atoms to occupy crystalline lattice sites during the atomic rearrangement that occurs during phase transformation, without requiring heating. However, in the described embodiment, where the semiconductor is silicon, the resulting phase or phases is the metastable mixed HPP, which appears to have only a slightly lower electrical conductivity (at comparable boron doping levels) than the ideally desired Si-I end-phase that is the standard phase of silicon used commercially. However, the HPP can be readily further transformed to Si-I by a subsequent relatively low temperature heating step, as described below. It will be apparent to those skilled in the art that this low temperature heating step 110 could alternatively be combined with the pressure application and removal step 108 by heating the sample during at least the pressure removal. However, if the desired end-phase is HPP silicon, then the heating step may not be required. On the other hand, the inventors have found that heating the silicon during the loading step to even just a little above room temperature (e.g., about 50° C.) facilitates the pressure induced phase transformations so that phase transformations can be induced at a lower maximum applied pressure than is required at lower temperatures.

If the doping process is applied to a different semiconductor, then the heating (whether simultaneous with the loading and/or unloading steps or otherwise) may not be advantageous, depending of course on the specific properties of the phase or phases formed by the application and release of pressure, and whether that phase or phases is or are metastable or otherwise able to be transformed at a relatively low temperature to another phase with more desirable properties. It is also possible that some combinations of dopants and semiconductor phases may be such that the dopant has an undesirably low solubility in the first phase formed by the application and release of pressure, and a much higher solubility in the final phase formed by the subsequent heat treatment (although as indicated above, the heating may be simultaneous with at least the pressure removal step so that the final phase is effectively formed directly).

3×3 arrays of indentations were formed in individual samples prepared as described above, and the I-V characteristics of the indented regions 1002 in the samples were measured using the indenter tip 406, as described above. Returning to FIG. 1, at step 110 the samples were heated to a temperature of 450° for a period of 30 minutes to transform the indented regions to polycrystalline Si-I, as shown in FIG. 11.

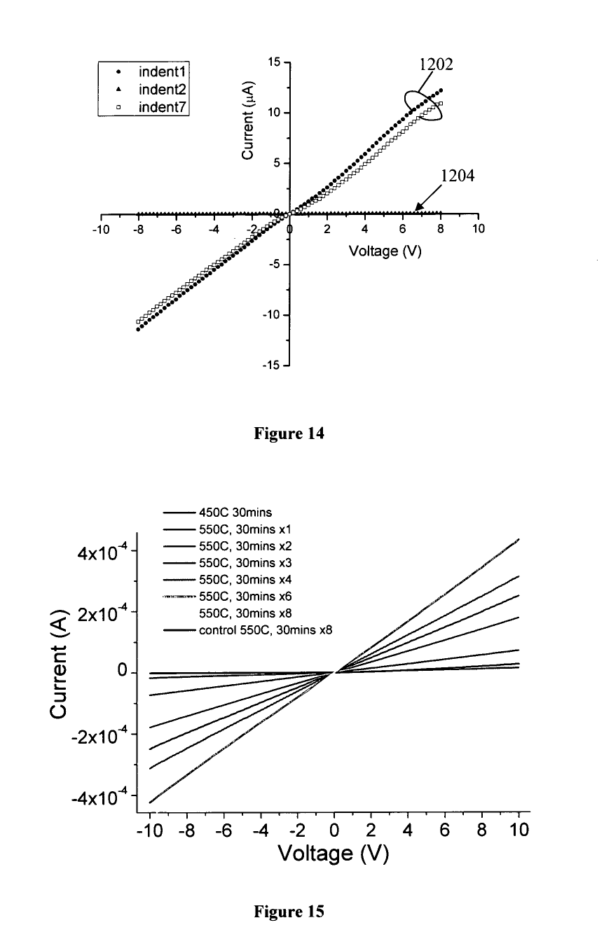

FIG. 14 is a graph showing the I-V characteristics 1202 of three indents formed in a sample implanted with 20 keV boron to a fluence of 1×10¹⁴ cm⁻², indented, and then annealed as described above. The I-V characteristics 1202 of most samples were essentially linear and Ohmic. This remarkable result indicates that boron-doped polycrystalline Si-I regions can be formed at a temperature of only 450° C., and indeed the inventors have found that this is possible at temperatures as low as 175° C. if longer annealing times are used (see FIG. 19, described below). For example, at 200° C. the anneal time is 30 mins. Existing techniques for producing doped crystalline Si-I from a-Si require the a-Si to first be recrystallized to Si-I (at a temperature in excess of 600° C. for typically more than 1 hour) which needs to be followed by an activation anneal of up to 900° C. (for at least a few seconds) to fully activate the dopant.

By measuring the resistance of indented lines 1008 (as described above) after low temperature annealing, a direct measurement of the resistance of the doped polycrystalline Si-I formed by the doping process can be made without the complications of contacts made with the indentation tip and sub-surface interfaces. FIG. 15 is a graph showing a series of I-V curves taken from an indented line 1008 in a boron-implanted sample following annealing. Following indentation and an anneal at 450° C. for 30 mins, the resistance of the polycrystalline Si-I line returns to a value close to that of the a-Si before indentation. However, following annealing at 550° C. for cumulative 30 minute periods, the resistivity decreases and begins to saturate after a total cumulative annealing time of about 3-4 hours. The polycrystalline Si-I line at this point is an order of magnitude more resistive than the same line before any annealing (i.e., when it was therefore composed of high pressure phases). However, this is expected because the polycrystalline Si-I formed by the doping process has a very small grain size: such fine grain polysilicon would be expected to be far more resistive if it was undoped.

As described above, not every sample indented under the same conditions as described above produces the mixed high pressure phases Si-III/Si-XII, with some samples returning to an amorphous phase on pressure release. It is observed that these samples, when annealed as described above, do not result in Ohmic behaviour, but rather remain electrically insulating, as shown by the data 1204 in FIG. 14 for such a sample. This is not surprising as the amorphous phase is relatively insulating, and the thermal processing of 450° C. at 30 minutes is insufficient to recrystallise the amorphous phase.

It is also observed that the variation in I-V characteristics described above is significantly reduced on annealing, with only a relatively small scatter in the I-V characteristics, as shown by the lines 1202 in FIG. 14 for the samples implanted with 20 keV boron to the lower fluence. It is believed that the variation in I-V characteristics prior to annealing is largely due to the random statistical nature of phase nucleation on pressure release. For example, as shown in FIG. 12, the number, dimensions, and distribution of amorphous inclusions 1006 within the mixed high pressure phase region 1004 may be subject to substantial variations due to the random nature of phase nucleation under these conditions. However, following the low temperature thermal processing step described above, it is found that both the mixed phase region 1004 and the amorphous inclusions 1006 anneal to the Si-I phase during annealing, as illustrated schematically in FIG. 13. Thus most of the cause of the variations is removed by this processing step. Similar behaviour is observed for the higher boron fluence samples.

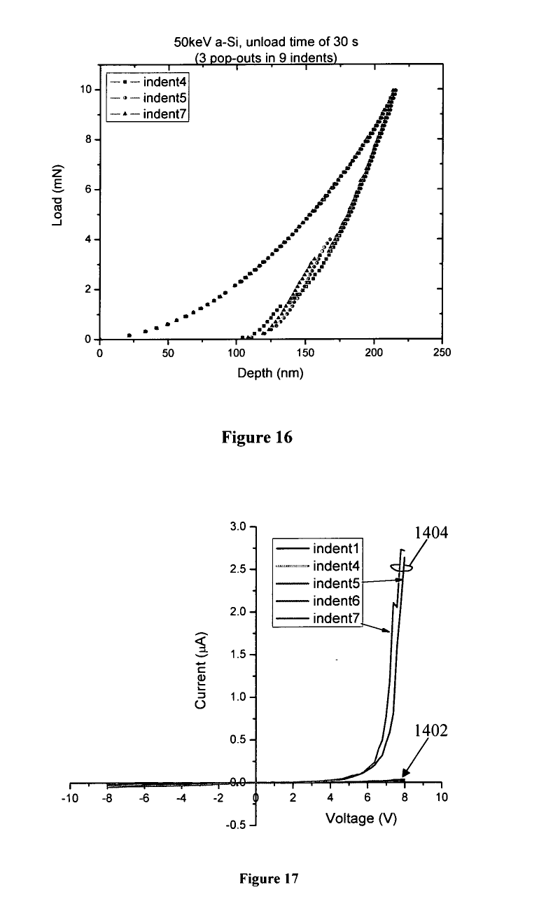

The above behaviour is observed for samples implanted with boron at an energy of 20 keV. However, samples implanted at the lower energy of only 10 keV do not exhibit Ohmic behaviour, but rather are similar to samples in which no boron was implanted. For example, FIG. 16 is a graph showing the load/unload curves for three indentations that exhibit the “pop-out” event indicating the formation of the HPPs in samples that were not implanted with boron. Of the nine indents in one particular 3×3 array, these three indentations were the only ones to exhibit pop-out events, with the unload curves for the other six indentations displaying a smooth decrease in penetration depth with decreasing load. FIG. 17 is a graph showing the I-V characteristics of five of these nine indentations. Because no boron has been implanted into the indented region, the samples have a Schottky-type rectifying behaviour, even following annealing. The samples implanted with boron at the lower energy of 10 keV also showed this type of behaviour. It is observed that, if no pop-out event is evident from the indentation load/unload curve, the indented region remains predominantly insulating, as indicated by a flat I-V characteristic 1402. In contrast, the rectifying I-V characteristics 1404 are only observed in samples whose load/unload curves exhibited pop-out events, indicating the formation of the HPPs, and which were subsequently transformed to polycrystalline Si-I by annealing.

Notwithstanding the above, it has been observed that not all samples exhibiting pop-out events also exhibit rectifying behaviour after annealing. For example, in this case it was observed that one of the three samples exhibiting pop-out events also had a flat I-V characteristic 1402. It is believed that a threshold volume of the high-pressure Si-III/Si-XII is required to form polycrystalline Si-I by thermal treatment as described above. Accordingly, in this case the sample “indent 4”, which showed the smallest pop-out event, which also occurred at the lowest applied load of all pop-out events, falls below this threshold volume. This is believed to be caused by the nucleation-limited nature of the Si-II to HPP transformation under these conditions. When larger volumes of Si-II are formed on loading, it is more likely that the HPPs will be nucleated during unloading. If the HPP are not nucleated at all (such as when the unloading is fast), then the region transforms to a-Si.

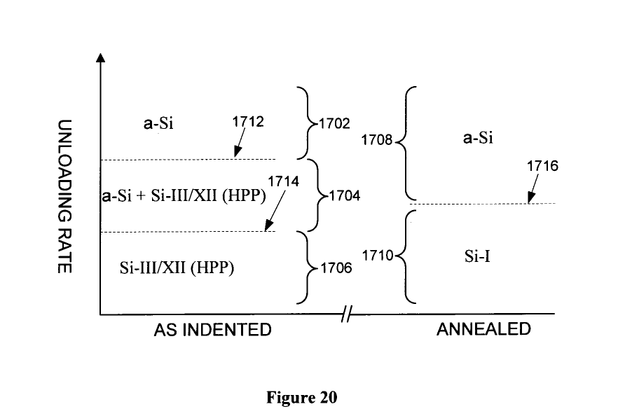

The various states of this material system are represented schematically in FIG. 20. The three regions 1702, 1704, 1706 to the left of this Figure represent the three states of the system immediately following indentation, whereas the two states 1708, 1710 to the right of this Figure represent the two states of the system following low-temperature thermal treatment in the 175-450° C. regime as described above. The vertical distribution of these states corresponds to the rate of pressure release during the indentation (also referred to as the “unloading rate”), with the rate of pressure release increasing towards the top of the Figure.

Thus high unloading rates above a certain threshold value represented by the dashed line 1712 result in the formation of predominantly a-Si. Conversely, unloading rates below a second threshold value represented by the second dashed line 1714 result in the indented region transforming almost entirely to the high-pressure phases Si-III/Si-XII. The region 1704 between the two threshold values 1712, 1714 produces a variable mixture of amorphous silicon and the high pressure phases. It should be understood that the threshold unloading rates 1712, 1714 are not fixed values, but will depend on process conditions, including the geometry and dimensions of the pressure applicator, the physical structure of the material to which the pressure is applied (e.g., whether in bulk or layer form, and the thickness(es) of any layer(s)), and the particular semiconductor used.

Following the low temperature annealing or heat treatment, the end result is one of the two phases 1708, 1710 to the right-hand side of FIG. 20. Specifically, if the volume fraction of a-Si is above a threshold amount represented schematically by the dashed line 1716, then the post-annealing state of the system is a-Si 1708. Conversely, if the fraction of a-Si is below the threshold amount 1716, then the heat treatment transforms the indented region to Si-I 1710.

In order to determine the annealing conditions that will result in the formation of Si-I 1710, the annealing kinetics of the mixed high-pressure phases Si-III/XII were measured in an initially crystalline Si-I sample indented to form the high-pressure phases. All of the cases examined here were indents that gave ‘pop-outs’ in the earlier stages of unloading and hence the volume of a-Si was below the threshold 1716 for transformation to Si-I on subsequent annealing.

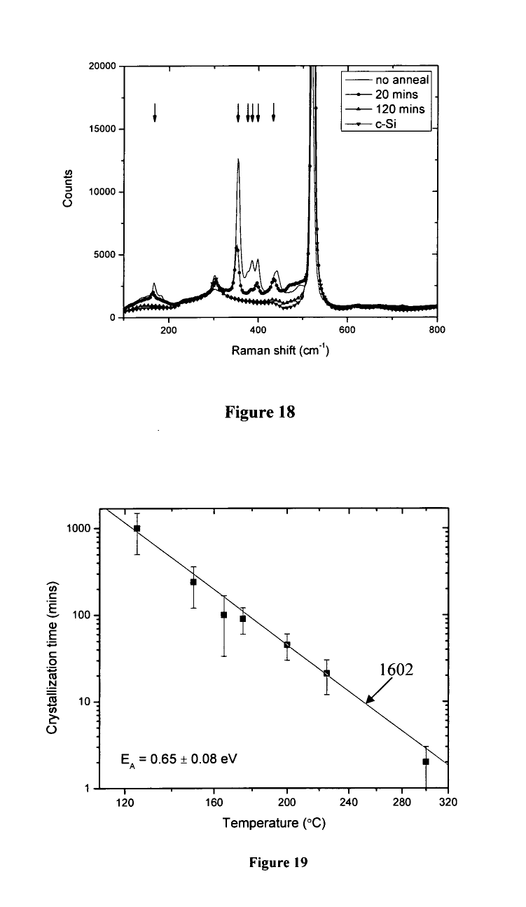

The amount of the high-pressure phases was measured qualitatively using Raman spectroscopy, and FIG. 18 shows representative Raman spectra from indented samples annealed at 175° C. for times of 0, 20, and 120 minutes, together with a Raman spectrum from unindented Si-I. Raman spectra such as these were used to determine the shortest annealing time required at each annealing temperature in order to completely transform the high pressure phases to Si-I, the criterion for complete transformation being when the peaks associated with the high-pressure phases disappear from the Raman spectrum and thus the spectrum becomes essentially identical to the spectrum for Si-I. FIG. 19 is a graph showing the resulting crystallization time as a function of annealing temperature, and the straight line 1602 is a line of best fit to the data points, and indicates an activation energy of 0.65 plus/minus 0.08 eV. However, it should be borne in mind that these measurements are for indentation of a crystalline Si-I sample. Although similar measurements in relaxed a-Si samples provide a similar activation energy, the annealing takes at least four times as long as it does in a Si-I sample.

Returning to FIG. 20, it will be recalled that the low-temperature annealing transforms the indented region to the polycrystalline Si-I phase 1710 only if the volume fraction of a-Si is below a threshold amount. Also as described above, depending also on the indentation conditions, in particular the rate of pressure release, the phase transformations to the HPP are believed to be nucleation-controlled and the nucleation of the final phases is statistical in nature, so that indentations performed under nominally identical conditions can produce very different phase compositions. Accordingly, if the indentation conditions are in such a nucleation-limited regime where the final phases can vary significantly, it is important to be able to assess what final phases are actually present in order to provide reproducible results.

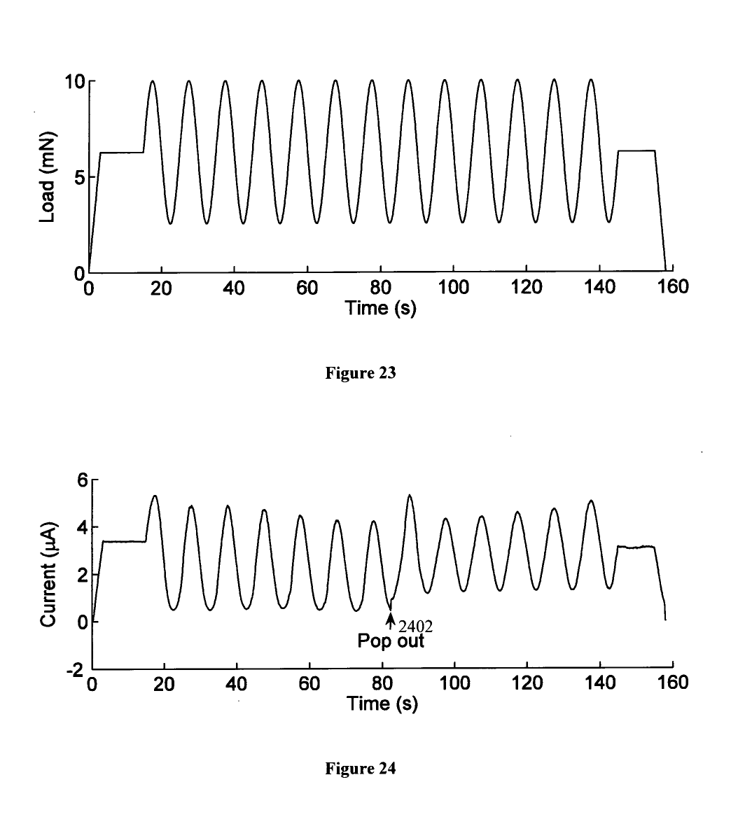

Upon loading with a rigid indenter, the diamond cubic Si-I beneath the indenter transforms to a metallic Si-II phase as the local hydrostatic and shear stresses become sufficiently large to promote the Si-I-to-Si-II transformation. Upon fast unloading, the Si-II material can transform almost entirely to a-Si. Upon slow unloading, some of the Si-II material may transform to high pressure phases (HPP) with the remaining Si-II material transforming to a-Si. As the formation of HPP is known to coincide with the presence of a pop-out event during unloading, the occurrence of the event indicates the transformation to HPP of at least some of the Si-II material. However, for small transformed volumes of nanometer scale, the volume ratio of the two phases, HPP and a-Si, can vary even between two indents made under the same loading and unloading conditions, largely because of the nucleation-driven, probabilistic nature of the Si-II to HPP transformation. Consequently, the higher volumes of Si-II produced by the indentation of larger areas are more likely to nucleate HPP, and are therefore more reproducible. For example, at slow unloading rates for spherical indenters of diameters greater than 4 μm, it is possible to achieve volumes of HPP in the residual indents that exceed the threshold in almost 100% of cases. For significantly smaller indents, below 100 nm for example, this is not always the case, but in such cases cyclic loading (as shown in FIGS. 23 and 24 for example) can be used to guarantee the formation of HPP.

On the basis that HPP is more dense than a-Si (e.g., ≈1.13ρ_{a-Si}), the indented material with a higher ratio of HPP to a-Si should have a smaller volume. Furthermore, the resulting volume of the indented material scales inversely with the residual indentation depth. It may therefore be possible to predict the ratio of HPP to a-Si in the indented material based on the residual indentation depth alone. If so, the greater the residual indentation depth, the greater the amount of HPP in the indented material. The residual indentation depth can be determined by extrapolating the indentation depth at zero force by curve-fitting of an appropriate (preferably power-law) function to the load-displacement curve towards the end of unloading cycle.

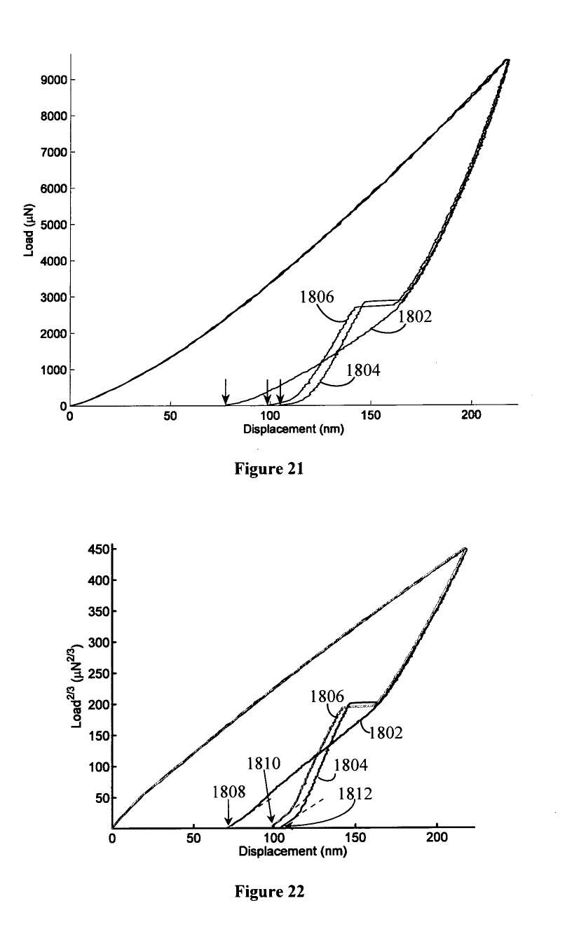

FIG. 21 is a graph showing the relationship between the applied load and the displacement relative to the original surface for three indentations made with the sphero-conical indenter using the same loading and unloading conditions. Specifically, the load was applied at a rate of 1 mNs⁻¹, and removed at a rate of 0.333 mNs⁻¹, with no holding period of the maximum applied load. It will be apparent from the graph that the unloading behaviour of these samples are substantially different from one another, with one curve 1802 not displaying any pop-out event, and the other curves 1804, 1806 both displaying pop-out events, but of substantially different magnitudes. By scaling the load to the two-thirds power, as shown in FIG. 22, the final portion of these curves becomes linear, facilitating the extrapolation of the curves to determine a final displacement depth. The three corresponding final displacements determined by this method are indicated by the three arrows 1808, 1810, and 1812, clearly indicating an increase in proportions of the high-pressure phases with increasing displacement depth.

In addition to being able to assess the volume fraction of high-pressure phases in the indented region, particularly for nano-scaled indents, it is also highly desirable to be able to ensure that this volume fraction is above the threshold amount represented schematically in FIG. 20 by the dashed line 1716, so that low-temperature annealing can be applied to transform the indented region to Si-I 1710. To this end, repeated or cyclic indentation can be applied to a specific region so that, if the volume fraction of high-pressure phases is assessed to be below the desired threshold, the indented region can be simply re-indented one or more times until the volume fraction is at least equal to the desired threshold. To this end, a cyclic or periodic load can be applied to the indenter tip 406, as shown in FIG. 23, for example.

In addition to the monitoring of final displacement depth as described above, the electrical current conducted through the indented region can also be used as an indicator of the phases produced by indentation. FIG. 24 is a graph showing the current as a function of time, produced by applying the periodic force shown in FIG. 23 to one sample. With the repeated cyclic application of load to the indented region, at some point the region transforms during unloading to the HPP, causing a pop-out event that coincides with an irregular change 2402 in the measured current.

The HPPs are significantly more electrically conducting than a-Si, and the mechanical properties of the indentation end phases indicates that these HPP present at the maximum applied load in FIG. 24 are not transformable back to the metallic Si-II phase under these conditions. Thus, cyclic loading can be used to ensure that large volumes of HPP form on unloading, thus guaranteeing the subsequent transformation to poly-Si-I on low temperature annealing.

The processes described above are particularly useful for forming doped polysilicon at temperatures well below those normally required to form doped polysilicon; i.e., in the absence of the application and removal of pressure, as described above. Accordingly, the doping processes described herein can be used to form highly conducting features in a sample, wafer, or thin film (e.g., TFT) device without having to expose that sample, wafer, or thin film to substantially higher temperatures that may degrade those entities. For example, in the flat panel industry, amorphous silicon can be deposited on a glass substrate, and then processed as described above to form doped polysilicon without exposing the glass substrate to undesirably high temperatures. It will be apparent to those skilled in the art that a wide variety of similar and other applications can be envisaged.

Although the doping process described is particularly advantageous when applied to produce a doped crystalline phase of a semiconductor from an amorphous phase containing dopant atoms (as described above), it will be apparent that the process can also be applied to an initially crystalline phase or phases of a semiconductor. Indeed, the initial and final transformed phases can even be the same.

Although the doping process has been described above in terms of forming doped silicon, it will be apparent to those skilled in the art that the process can equally be applied to other semiconductors, where the application and release of pressure to one phase of a semiconductor containing dopant atoms causes the semiconductor to undergo at least one phase transformation to form a doped crystalline phase or amorphous phase. Normally, the activation of a dopant in a semiconductor is thermally activated and requires relatively high temperatures to facilitate the replacement of atoms of the semiconductor by atoms of the dopant species such that the latter are located substantially at substitutional sites within the crystalline lattice structure. However, the doping process can achieve this essentially athermally (or at least at substantially reduced temperatures) by allowing the dopant atoms to occupy crystalline lattice sites during the atomic rearrangement that occurs during phase transformation. Additionally, if the resulting phase is metastable, then a further phase transformation to a final desired phase may be induced by heating to a relatively low temperature. In particular, the temperature can be substantially lower than that required to activate the dopant in the end phase without the use of pressure-induced phase transformation. Moreover, where the initial phase is amorphous, existing doping processes rely on a thermally induced phase transformation to a crystalline phase, also requiring exposure to relatively high temperatures. The doping processes described herein allow these undesirable high temperature/high thermal budget processing steps to be avoided.

Finally, International Patent Application No. PCT/AU2006/000786, entitled “A Patterning Process” describes a related process whereby pressure is applied and released from one or more regions of a first phase of a semiconductor to create one or more corresponding transformed regions of a second phase of the semiconductor. The transformed regions can be produced in essentially any desired shape and configuration, and the process is therefore referred to as a patterning process. Because the transformed regions generally have different physical properties than the untransformed region(s) of the semiconductor, the patterning process can be used to create functional elements of devices such as conducting pathways, electronic devices (including thin film transistors for display devices), solar cells, optical devices, mechanical structures, and so on. In addition to forming such elements, it will be apparent that the patterning process can also be considered to be a form of maskless lithography, and the changed physical properties of the transformed regions can include a change in the removal rate when subjected to a subtractive process such as etching.

It will be apparent to those skilled in the art that the doping processes described herein can be used to enhance the contrast between the localised transformed or patterned regions produced by the patterning process. For example, patterned regions can be formed and doped simultaneously. The changed electrical conductivity of the transformed regions even in the absence of dopant activation can be enhanced by incorporating inactive dopant atoms into the semiconductor prior to patterning so that the transformed patterned regions are doped while the untransformed regions are not. As described above, the initial and final phases could even be the same so that, for example, the net effect is to produce one or more locally doped regions of the same phase as the unprocessed one or more undoped regions.

Many modifications will be apparent to those skilled in the art without departing from the scope of the present invention as hereinbefore described with reference to the accompanying drawings.

1. A doping process, including:
applying pressure to at least one first phase of a semiconductor containing an electrically inactive dopant and removing said pressure to cause at least one phase transformation of said semiconductor to at least one second phase, wherein said at least one phase transformation activates said dopant so that said at least one second phase includes at least one doped phase of said semiconductor in which said dopant is electrically active.

2. The process of claim 1, wherein said applying and removal of pressure includes applying pressure to one or more localised regions of said semiconductor and removing said pressure to cause at least one phase transformation of said one or more localised regions of said semiconductor, wherein said at least one phase transformation activates said dopant to form one or more localised regions of a doped phase of said semiconductor.

3. The process of claim 1, including heating said at least one second phase to transform said at least one second phase to at least one third phase, said at least one third phase including at least one doped phase of said semiconductor in which said dopant is electrically active;
wherein said heating would be insufficient to thermally activate said dopant in said at least one first phase of said semiconductor in the absence of pressure-induced phase transformation.

4. The process of claim 1, including heating said semiconductor during at least the removal of said pressure to cause the formation of said at least one doped phase;
wherein said heating would be insufficient to thermally activate said dopant in said at least one first phase of said semiconductor in the absence of pressure-induced phase transformation.

5. The process of claim 1, including heating said semiconductor during the application of said pressure to facilitate a phase transformation of said semiconductor.

6. A doping process, including:
applying pressure to at least one first phase of a semiconductor containing an electrically inactive dopant and removing said pressure to transform said semiconductor to at least one second phase; and
heating said at least one second phase to transform said at least one second phase to at least one third phase, said at least one third phase including at least one doped phase of said semiconductor in which said dopant is electrically active;
wherein said heating would be insufficient to thermally activate said dopant in said at least one first phase of said semiconductor in the absence of pressure-induced phase transformation.

7. The process of claim 6, wherein said semiconductor is silicon and said temperature is substantially below 600° C.

8. The process of claim 6, wherein said semiconductor is silicon and said temperature is at most about 450° C.

9. The process of claim 6, wherein said semiconductor is silicon and said temperature is at most about 175° C.

10. The process of claim 6, wherein said step of applying pressure to said semiconductor and removing said pressure to transform said semiconductor includes:
(i) applying pressure to said semiconductor and removing said pressure;
(ii) determining whether said step (i) of applying and removing pressure has substantially transformed said semiconductor to said at least second phase; and
(iii) repeating steps (i) and (ii) until it is determined that said semiconductor has been substantially transformed to said at least one second phase.

11. The process of claim 10, wherein said step of determining whether said semiconductor has been substantially transformed includes determining a final surface displacement, the determination of whether said semiconductor has been substantially transformed to said at least second phase being made on the basis of said final surface displacement.

12. The process of claim 10, wherein said step of determining whether said semiconductor has been substantially transformed includes determining at least one electrical conductivity of said semiconductor, the determination of whether said semiconductor has been substantially transformed to said at least one second phase being made on the basis of said at least one electrical conductivity.

13. The process of claim 10, wherein said step of determining whether said semiconductor has been substantially transformed includes determining an I-V curve of said semiconductor, the determination of whether said semiconductor has been substantially transformed to said at least one second phase being made on the basis of said I-V curve.

14. The process of claim 1, wherein said at least one first phase of said semiconductor includes said at least one second phase of said semiconductor.

15. The process of claim 1, wherein said at least one first phase of said semiconductor does not include said at least one second phase of said semiconductor.

16. The process of claim 1, wherein said at least one doped phase includes at least one crystalline phase.

17. The process of claim 1, wherein said at least one first phase of said semiconductor includes an amorphous phase of said semiconductor.

18. The process of claim 17, wherein said amorphous phase is a relaxed amorphous phase.

19. The process of claim 18, including forming said relaxed amorphous phase by relaxing an unrelaxed amorphous phase of said semiconductor.

20. The process of claim 1, wherein said semiconductor is silicon.

21. A doped semiconductor formed by the process of claim 1.
